(19) United States
(12) Patent Application Publication
(10) Pub. No.: US 2026/0304960 A1
(43) Pub. Date: Oct. 1, 2026

(54) SEMICONDUCTOR DEVICE WITH BOTTOM INSULATING LAYER AND METHOD FOR FABRICATING THE SAME

(71) Applicant: NANYA TECHNOLOGY CORPORATION, NEW TAIPEI CITY (TW)

(72) Inventors: WEI-ZHENG WU, NEW TAIPEI CITY (TW); YI-LONG WONG, NEW TAIPEI CITY (TW)

(21) Appl. No.: 19/208,081

(22) Filed: May 14, 2025

Related U.S. Application Data
(63) Continuation of application No. 19/093,510, filed on Mar. 28, 2025.

(51) Int. Cl. H10D 89/00; H01L 21/762

(52) U.S. Cl. CPC H10D 89/00; H10W 10/014; H10W 10/17

(57) ABSTRACT

The present application discloses a semiconductor device and a method for fabricating the semiconductor device. The semiconductor device includes a substrate; an indentation inwardly positioned in the substrate; a bottom insulating layer including a lower portion conformally positioned along the indentation, and an upper portion conformally positioned on the lower portion and within the indentation; a first top insulating layer conformally positioned on the upper portion and within the indentation; and a first filling layer positioned on and surrounded by the first top insulating layer. A sidewall of the indentation is substantially vertical.

### CROSS-REFERENCE TO RELATED APPLICATION

This application is a continuation application of U.S. Non-Provisional application Ser. No. 19/093,510 filed Mar. 28, 2025, which is incorporated herein by reference in its entirety.

### TECHNICAL FIELD

The present disclosure relates to a semiconductor device and a method for fabricating the semiconductor device, and more particularly, to a semiconductor device with a bottom insulating layer and a method for fabricating the semiconductor device with the bottom insulating layer.

### DISCUSSION OF THE BACKGROUND

Semiconductor devices are used in a variety of electronic applications, such as personal computers, cellular telephones, digital cameras, and other electronic equipment. The dimensions of semiconductor devices are continuously being scaled down to meet the increasing demand of computing ability. However, a variety of issues arise during the scaling-down process, and such issues are continuously increasing. Therefore, challenges remain in achieving improved quality, yield, performance, and reliability and reduced complexity.

This Discussion of the Background section is provided for background information only. The statements in this Discussion of the Background are not an admission that the subject matter disclosed in this section constitutes prior art to the present disclosure, and no part of this Discussion of the Background section may be used as an admission that any part of this application, including this Discussion of the Background section, constitutes prior art to the present disclosure.

### SUMMARY

One aspect of the present disclosure provides a semiconductor device including a substrate; an indentation inwardly positioned in the substrate; a bottom insulating layer including a lower portion conformally positioned along the indentation, and an upper portion conformally positioned on the lower portion and within the indentation; a first top insulating layer conformally positioned on the upper portion and within the indentation; and a first filling layer positioned on and surrounded by the first top insulating layer. A sidewall of the indentation is substantially vertical.

Another aspect of the present disclosure provides a semiconductor device including a substrate; a first filling layer positioned in the substrate; a first top insulating layer including a U-shaped cross-sectional profile, surrounding the first filling layer, and positioned between the substrate and the first filling layer and; a bottom insulating layer including an upper portion including a U-shaped cross-sectional profile, surrounding the first top insulating layer, and positioned between the substrate and the first top insulating layer, and a lower portion including a U-shaped cross-sectional profile, surrounding the upper portion, and positioned between the substrate and the upper portion. A sidewall of the upper portion is substantially vertical.

Another aspect of the present disclosure provides a method for fabricating a semiconductor device including providing a substrate; forming an indentation in the substrate; conformally forming a lower portion within the indentation; and conformally forming an upper portion on the lower portion; conformally forming a first top insulating layer on the lower portion and within the indentation; and forming a first filling layer on the first top insulating layer, completely filling the indentation. The lower portion and the upper portion together configure a bottom insulating layer. A process temperature for forming the lower portion of the bottom insulating layer is less than 500° C., and a process temperature for forming the upper portion of the bottom insulating layer is greater than 500° C.

Due to the design of the semiconductor device of the present disclosure, the lower portion of the bottom insulating layer may be deposited through a low-temperature reaction (e.g., less than 500° C.) in a single-gas environment (oxygen gas only), preventing side reactions between the substrate and precursors (e.g., hydrogen gas and/or chlorine). This helps maintain an intact trench profile and avoids adverse effects on the electrical characteristics of the semiconductor device. As a result, the yield and performance of the semiconductor device may be improved.

The foregoing has outlined rather broadly the features and technical advantages of the present disclosure in order that the detailed description of the disclosure that follows may be better understood. Additional features and advantages of the disclosure will be described hereinafter, and form the subject of the claims of the disclosure. It should be appreciated by those skilled in the art that the conception and specific embodiment disclosed may be readily utilized as a basis for modifying or designing other structures or processes for carrying out the same purposes of the present disclosure. It should also be realized by those skilled in the art that such equivalent constructions do not depart from the spirit and scope of the disclosure as set forth in the appended claims.

### BRIEF DESCRIPTION OF THE DRA WINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

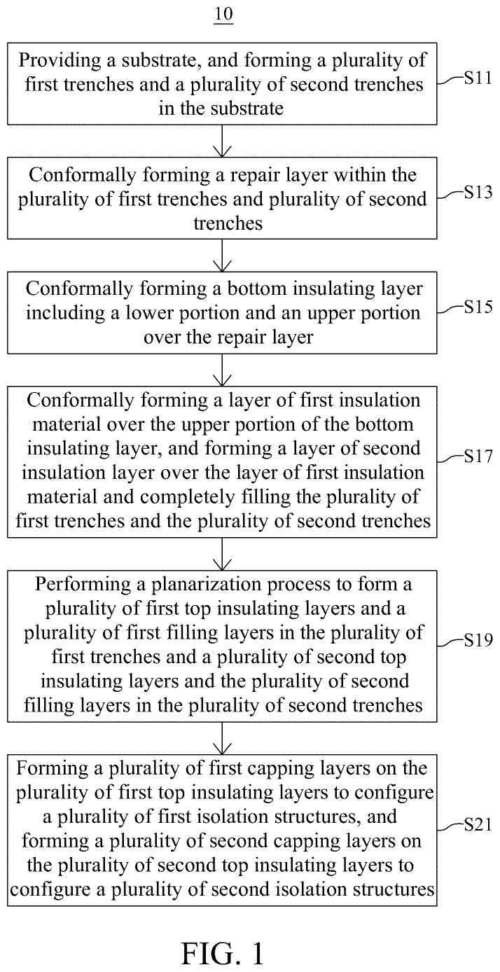

FIG. 1 illustrates, in a flowchart diagram form, a method for fabricating a semiconductor device in accordance with one embodiment of the present disclosure; and

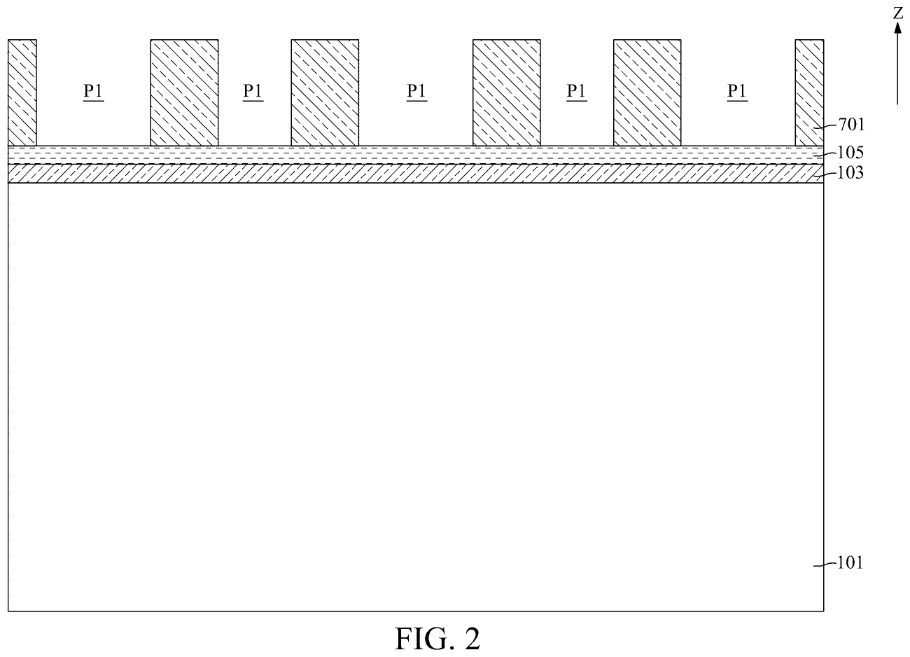

FIGS. 2 to 12 illustrate, in schematic cross-sectional view diagrams, a flow for fabricating the semiconductor device in accordance with one embodiment of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

It should be understood that when an element or layer is referred to as being “connected to” or “coupled to” another element or layer, it can be directly connected to or coupled to another element or layer, or intervening elements or layers may be present.

It should be understood that, although the terms first, second, etc. may be used herein to describe various elements, these elements should not be limited by these terms. Unless indicated otherwise, these terms are only used to distinguish one element from another element. Thus, for example, a first element, a first component or a first section discussed below could be termed a second element, a second component or a second section without departing from the teachings of the present disclosure.

Unless the context indicates otherwise, terms such as “same,” “equal,” “planar,” or “coplanar,” as used herein when referring to orientation, layout, location, shapes, sizes, amounts, or other measures do not necessarily mean an exactly identical orientation, layout, location, shape, size, amount, or other measure, but are intended to encompass nearly identical orientation, layout, location, shapes, sizes, amounts, or other measures within acceptable variations that may occur, for example, due to manufacturing processes. The term “substantially” may be used herein to reflect this meaning. For example, items described as “substantially the same,” “substantially equal,” or “substantially planar,” may be exactly the same, equal, or planar, or may be the same, equal, or planar within acceptable variations that may occur, for example, due to manufacturing processes.

In the present disclosure, a semiconductor device generally means a device which can function by utilizing semiconductor characteristics, and an electro-optic device, a light-emitting display device, a semiconductor circuit, and an electronic device are all included in the category of the semiconductor device.

It should be noted that, in the description of the present disclosure, above (or up) corresponds to the direction of the arrow of the Z direction, and below (or down) corresponds to the opposite direction of the arrow of the Z direction.

FIG. 1 illustrates, in a flowchart diagram form, a method 10 for fabricating a semiconductor device 1 in accordance with one embodiment of the present disclosure. FIGS. 2 to 12 illustrate, in schematic cross-sectional view diagrams, a flow for fabricating the semiconductor device 1 in accordance with one embodiment of the present disclosure.

With reference to FIGS. 1 to 5, at step S11, a substrate 101 may be provided, and a plurality of first trenches TR1 and a plurality of second trenches TR2 may be formed in the substrate 101.

With reference to FIG. 2, the substrate 101 may include a bulk semiconductor substrate. The bulk semiconductor substrate may be formed of, for example, an elementary semiconductor, such as silicon or germanium; a compound semiconductor, such as silicon germanium, silicon carbide, gallium arsenide, gallium phosphide, indium phosphide, indium arsenide, indium antimonide, or other III-V compound semiconductor or II-VI compound semiconductor; or combinations thereof.

In some embodiments, the substrate 101 may include a semiconductor-on-insulator structure which consists of, from bottom to top, a handle substrate, an insulator layer, and a topmost semiconductor material layer. The handle substrate and the topmost semiconductor material layer may be formed of the same material as the bulk semiconductor substrate aforementioned. The insulator layer may be a crystalline or non-crystalline dielectric material such as an oxide and/or nitride. For example, the insulator layer may be a dielectric oxide such as silicon oxide. For another example, the insulator layer may be a dielectric nitride such as silicon nitride or boron nitride. For yet another example, the insulator layer may include a stack of a dielectric oxide and a dielectric nitride such as a stack of, in any order, silicon oxide and silicon nitride or boron nitride. The insulator layer may have a thickness between about 10 nm and 200 nm.

It should be noted that, the term “about” modifying the quantity of an ingredient, component, or reactant of the present disclosure employed refers to variation in the numerical quantity that can occur, for example, through typical measuring and liquid handling procedures used for making concentrates or solutions. Furthermore, variation can occur from inadvertent error in measuring procedures, differences in the manufacture, source, or purity of the ingredients employed to make the compositions or carry out the methods, and the like. In one aspect, the term “about” means within 10% of the reported numerical value. In another aspect, the term “about” means within 5% of the reported numerical value. Yet, in another aspect, the term “about” means within 10, 9, 8, 7, 6, 5, 4, 3, 2, or 1% of the reported numerical value.

With reference to FIG. 2, a bottom hard mask layer 103 may be formed on the substrate 101. In some embodiments, the bottom hard mask layer 103 may be formed of, for example, silicon oxide. In some embodiments, the bottom hard mask layer 103 may be formed by performing a rapid thermal oxidation to the substrate 101 in an oxide/oxynitride atmosphere. In some embodiments, the temperature of the rapid thermal oxidation may be about 1000° C.

With reference to FIG. 2, a top hard mask layer 105 may be formed on the bottom hard mask layer 103. In some embodiments, the top hard mask layer 105 may be formed of, for example, silicon oxide. In some embodiments, the top hard mask layer 105 may be formed by, for example, chemical vapor deposition, plasma enhanced chemical vapor deposition. For example, the top hard mask layer 105 may be deposited by chemical vapor deposition using a silicate or silicon source, a number of doping sources, and an ozone source. In some embodiments, the doping sources may be optional. In some embodiments, the doping sources may be, for example, triethylborate, triethylphosphate, triethylphosphite, trimethylphosphate, or trimethylphosphite. In some embodiments, the silicate or silicon source may be, for example, tetramethylorthosilicate. The doping sources may result in impurity atoms such as phosphorus or boron in the top hard mask layer 105.

With reference to FIG. 2, a first mask layer 701 may be formed on the top hard mask layer 105. In some embodiments, the first mask layer 701 may be a photoresist layer and may include a trench pattern P1 of the plurality of first trenches TR1 and the plurality of second trenches TR2.

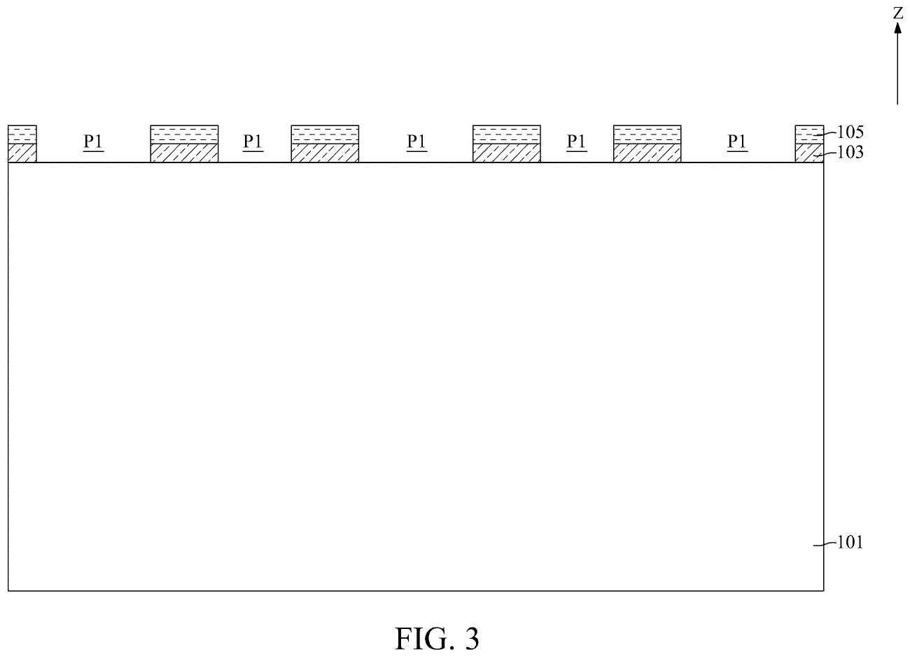

With reference to FIG. 3, a hard mask etching process may be performed using the first mask layer 701 as the mask to remove a portion of the top hard mask layer 105 and a portion of the bottom hard mask layer 103. After the hard mask etching process, the trench pattern P1 of the first mask layer 701 may be transferred to the top hard mask layer 105 and the bottom hard mask layer 103. The first mask layer 701 may be removed after the formation of the trench pattern P1. In some embodiments, the removal of the first mask layer 701 may be, for example, an ashing process or other applicable semiconductor processes.

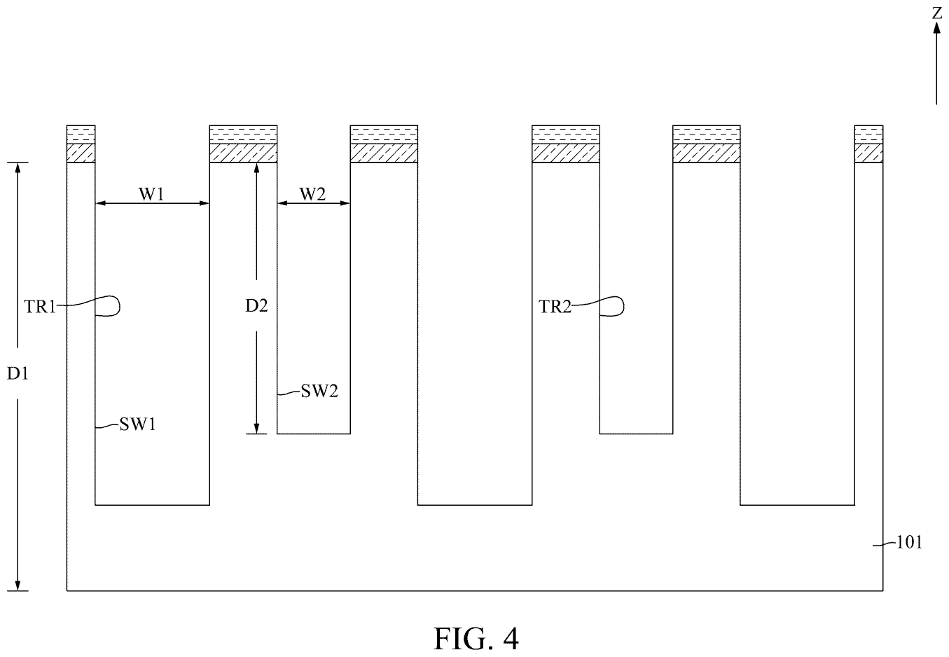

With reference to FIG. 4, a trench etching process may be performed, utilizing the bottom hard mask layer 103 and the top hard mask layer 105 as masks, to remove a portion of the substrate 101. This process results in the formation of the plurality of first trenches TR1 and the plurality of second trenches TR2 in the substrate 101. In some embodiments, the plurality of first trenches TR1 and the plurality of second trenches TR2 may be referred to as indentations of the substrate 101. In some embodiments, the sidewall SW1 of the first trench TR1 may be substantially vertical. In some embodiments, the sidewall SW2 of the second trench TR2 may be substantially vertical. In some embodiments, the aspect ratio of the first trench TR1 may be between about 4:1 and about 12:1. In some embodiments, the aspect ratio of the second trench TR2 may be between about 4:1 and about 12:1. In some embodiments, the width W1 of the first trench TR1 may be greater than the width W2 of the second trench TR2. In some embodiments, the depth D1 of the first trench TR1 may be greater than the depth D2 of the second trench TR2.

It should be noted that, in the description of the present disclosure, a surface is “substantially vertical” if there exists a vertical plane from which the surface does not deviate by more than three times the root mean square roughness of the surface.

In some embodiments, a post-etching cleaning process may be performed after the formation of the plurality of first trenches TR1 and the plurality of second trenches TR2. The post-etching cleaning process may include three stages with inter-stage rinses between stages. Detailedly, during the first stage of the post-etching cleaning process, a first cleaning solution may be applied to the intermediate semiconductor device after the formation of the plurality of first trenches TR1 and the plurality of second trenches TR2. The first cleaning solution may be rinsed by the first inter-stage rinse. During the second stage of the post-etching cleaning process, a second cleaning solution may be applied to the intermediate semiconductor device and the second cleaning solution may be subsequently rinsed by a second inter-stage rinse. During the third stage of the cleaning process, a third cleaning solution may be applied to the intermediate semiconductor device and then be rinsed by a post-stage rinse.

In some embodiments, during the first stage of the post-etching cleaning process, the intermediate semiconductor device may be spun at a rate between about 10 rpm and about 2000 rpm or between about 100 rpm and 1000 rpm. The first cleaning solution may be sprayed onto the intermediate semiconductor device to cover the entire front side of the intermediate semiconductor device. Simultaneously to applying the first cleaning solution onto the front side of the intermediate semiconductor device, water or other suitable solution may be applied to the backside of the intermediate semiconductor device to clean the backside of the intermediate semiconductor device.

In some embodiments, the first cleaning solution may include diluted hydrofluoric acid. The concentration of the first cleaning solution may be between about 5 parts deionized water to one part hydrofluoric acid and about 1000 parts deionized water to one part hydrofluoric acid, about 300 parts deionized water to one part hydrofluoric acid, or about 50 parts deionized water to one part hydrofluoric acid. Generally, the front side of the intermediate semiconductor device may be exposed to the first cleaning solution for a time sufficient to etch either a sacrificial oxide (typically around 50 angstroms to 200 angstroms) or a native oxide (typically around 10 angstroms.) In some embodiments, the process time of the first stage of the cleaning process may be between about 20 seconds and about 50 seconds, about 40 seconds, or about 30 seconds. In some embodiments, the process time of the first stage of the post-etching cleaning process may be between about 1 minutes and about 5 minutes.

In some embodiments, the first cleaning solution may further include fluoride compound(s), organic acid salt(s), and/or glyoxylic acid.

The fluorine compound(s) may be contained in the first cleaning solution as a component for removing the etching residue of the trench etching process. Examples of the fluorine compound(s) may include hydrofluoric acid and ammonium or amine fluoride salts such as, for example, ammonium fluoride, ammonium hydrogen fluoride, methylamine hydrofluoride, ethylamine hydrofluoride, propylamine hydrofluoride, tetramethylammonium fluoride, tetraethylammonium fluoride, ethanolamine hydrofluoride, methylethanolamine hydrofluoride, dimethylethanolamine hydrofluoride, and triethylenediamine hydrofluoride. In some embodiments, the concentration of the fluorine compound(s) in the first cleaning solution may be determined according to the composition of the etching residue. For example, the concentration of the fluorine compound(s) may be between about 0.1 mass % and about 5 mass % of the entire composition of the first cleaning solution, or between about 0.2 mass % and about 3 mass % of the entire composition of the first cleaning solution.

The organic acid salt(s) may include, for example, ammonium oxalate, ammonium tartrate, ammonium citrate, and ammonium acetate. The organic acid salt(s) may act as a pH adjusting agent(s) or buffer agent(s) in the first cleaning solution. The concentration of the organic acid salt(s) may be between about 0.1 mass % and about 10 mass % of the entire composition of the first cleaning solution, or between about 0.3 mass % and about 5 mass % of the entire composition of the first cleaning solution.

The glyoxylic contained in the first cleaning solution may serve as a corrosion inhibitor.

In some embodiments, the first cleaning solution may further include a resist removal component. Examples of the resist removal component include tetramethylammonium hydroxide and/or monomethanolamine.

The first inter-stage rinse may be performed after the first stage of the post-etching cleaning process. During the first inter-stage rinse, the intermediate semiconductor device after the first stage of the post-etching cleaning process may be rotated at between about 10 rpm and about 1000 rpm while being rinsed with deionized water. In some embodiments, the rinse temperature may be between about 19° C. and about 23° C. In some embodiments, the process time of the first inter-stage rinse may be between about 20 seconds and about 50 seconds, or about 30 seconds.

In some embodiments, the deionized water used for the first inter-stage rinse may be oxygenated or ozonated by dissolving oxygen gas or ozone gas before rinsing the intermediate semiconductor device. Dissolved oxygen or ozone may be added to the deionized water in a concentration of greater than 1 ppm to serve as an oxidant. For example, the concentration of dissolved oxygen or ozone may be between about 1 ppm and about 200 ppm or between about 2 ppm and about 20 ppm. For another example, the deionized water may be saturated with dissolved oxygen or ozone. Alternatively, hydrogen peroxide may be added to the deionized water in a concentration of greater than 100 ppm to serve as an oxidant. Whichever oxidant is used, it should have an oxidation potential sufficient to oxidize the most noble metal in the solution. Copper (Cu²⁺), with a standard reduction potential of 0.3V, is usually the most noble metal present. Therefore, a standard reduction potential of greater than 0.5V is desired. Oxygen or ozone will solvate the metal ions and prevent precipitation by oxidizing the metal ions that are in solution. This will help decrease the processing time by making the first inter-stage rinse more effective.

In some embodiments, the deionized water used for the first inter-stage rinse may be carbon dioxide dissolved into it to dissipate static electricity that builds up in the deionized water. Static electricity builds up in the deionized water may originate from the rotation of the intermediate semiconductor device. The dissolved carbon dioxide may also make the deionized water more acidic and therefore reduces any metallic contamination. In some embodiments, carbon dioxide may be dissolved into the deionized water in an amount sufficient to dissipate static electricity. For example, the amount of carbon dioxide dissolved into the deionized water may be sufficient to decrease the resistivity of the deionized water to less than 5 Megaohm·cm.

In some embodiments, the deionized water used for the first inter-stage rinse may have isopropyl alcohol, or any other liquid with a surface tension lower than that of the deionized water, added to it. Isopropyl alcohol may aid by making the deionized water spread out over the front side of the intermediate semiconductor device so that the chemicals are removed more quickly. Isopropyl alcohol may also help the rinse spin off of the intermediate semiconductor device during spinning. Alternatively, isopropyl alcohol vapor may be blown onto the front side of the intermediate semiconductor device while rinsing to assist the first inter-stage rinse.

In some embodiments, during the second stage of the post-etching cleaning process, the intermediate semiconductor device after the first inter-stage rinse may be spun at a rate between about 10 rpm and about 2000 rpm or between about 100 rpm and 1000 rpm. The second cleaning solution may be sprayed onto the intermediate semiconductor device to cover the entire front side of the intermediate semiconductor device. Simultaneously to applying the second cleaning solution onto the front side of the intermediate semiconductor device, water or other suitable solution may be applied to the backside of the intermediate semiconductor device to clean the backside of the intermediate semiconductor device.

In some embodiments, the second cleaning solution may be an alkaline solution including, for example, aqueous solutions of inorganic compounds such as sodium hydroxide, potassium hydroxide and ammonium hydroxide, and aqueous solution of organic compounds such as tetramethylammonium hydroxide and choline. The second cleaning solution may also include hydrogen peroxide. The purpose of the ammonium hydroxide and the hydrogen peroxide in the second cleaning solution is to remove particles and residual organic contaminants from the front side of the intermediate semiconductor device.

For example, in the present embodiment, the second cleaning solution may include ammonium hydroxide, hydrogen peroxide, and water. The ammonium hydroxide, hydrogen peroxide, and water may be present in concentrations defined by dilution ratios of between 5/1/1 to 1000 Jan. 1, respectively. In some embodiments, the ammonium hydroxide/hydrogen peroxide ratio may vary between 0.05/1 and 5/1. In some embodiments, no hydrogen peroxide is used at all. The ammonium hydroxide in the second cleaning solution would be from a solution of 28-29% w/w of ammonia to water. The hydrogen peroxide in the second cleaning solution would be from a solution of 31-32% w/w of hydrogen peroxide to water. The pH of the second cleaning solution may be between about 9 and 12 or between about 10 and 11 due to the ammonium hydroxide and the hydrogen peroxide.

In some embodiments, the second cleaning solution may further include dissolved hydrogen gas. The dissolved hydrogen gas in the second cleaning solution may provide cavitation (bubble creation) to the second cleaning solution. Providing cavitation to the second cleaning solution may enhance the post-etching cleaning process. In some embodiments, the concentration of the dissolved hydrogen gas may be between about 0.01 mg/L and about 5 mg/L or between about 0.1 mg/L and about 5 mg/L. In some embodiments, other suitable cavitation gases such as nitrogen, helium, Argon, or oxygen may also be used. For example, dissolved oxygen having concentration between about 1 mg/L and about 20 mg/L may be used in the second cleaning solution.

In some embodiments, the process time of the second stage of the post-etching cleaning process may be between about 30 seconds and about 100 seconds, between about 30 seconds and 90 seconds, or between about 30 seconds and about 60 seconds. In some embodiments, the temperature of the second cleaning solution may be between about 40° C. and about 85° C.

The second inter-stage rinse may be performed after the second stage of the post-etching cleaning process. The second inter-stage rinse may be performed with a procedure similar to the first inter-stage rinse, and descriptions thereof are not repeated herein.

In some embodiments, during the third stage of the post-etching cleaning process, the intermediate semiconductor device after the second inter-stage rinse may be spun at a rate between about 10 rpm and about 2000 rpm or between about 100 rpm and 1000 rpm. The third cleaning solution may be sprayed onto the intermediate semiconductor device to cover the entire front side of the intermediate semiconductor device. Simultaneously to applying the third cleaning solution onto the front side of the intermediate semiconductor device, water or other suitable solution may be applied to the backside of the intermediate semiconductor device to clean the backside of the intermediate semiconductor device.

In some embodiments, the third cleaning solution may be an acidic solution including, for example, aqueous solution of inorganic acids such as hydrochloric acid, hydrofluoric acid, sulfuric acid and nitric acid, and aqueous solution of organic acids such as oxalic acid, citric acid, malonic acid, malic acid, fumaric acid and maleic acid. In some embodiments, the third cleaning solution may also include hydrogen peroxide. The concentration of the acidic solution may be between about 0.001% and about 10% by weight or between about 0.01% and about 5% by weight. When the concentration is too low, the washing effect may not be obtained sufficiently. When the concentration is too high, metal-corrosion of the washing apparatus or the other related apparatus may occur.

A post-stage rinse may be performed after the third stage of the post-etching cleaning process. The post-stage rinse may be performed with a procedure similar to the first inter-stage rinse, and descriptions thereof are not repeated herein.

In some embodiments, the second stage and the third stage of the post-etching cleaning process may be optional. In other words, only the first stage of the post-etching cleaning process may be performed. In some embodiments, the third stage of the post-etching cleaning process may be optional. In other words, only the first stage and the second stage of the post-etching cleaning process may be performed.

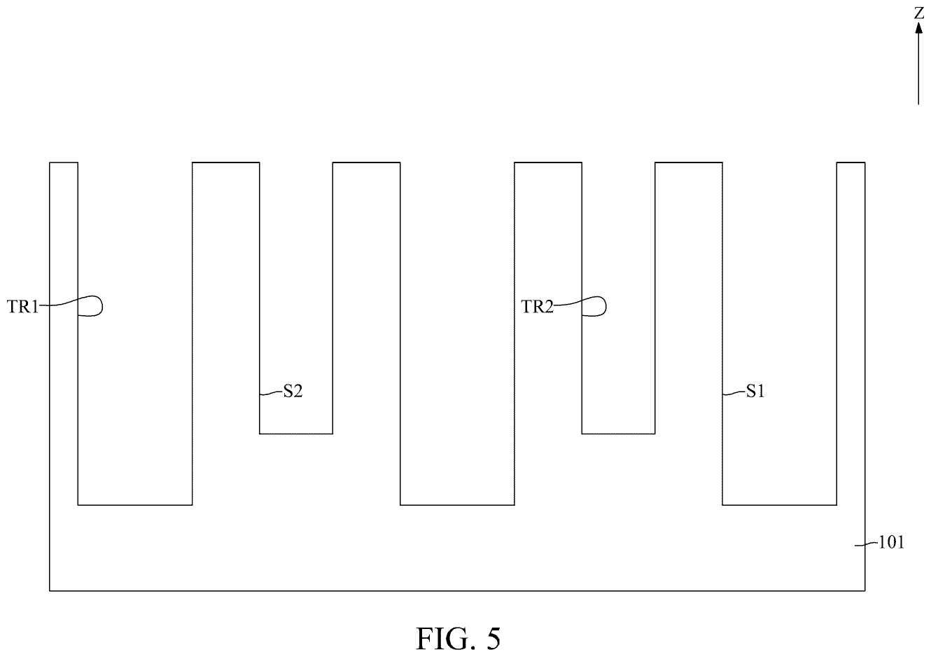

With reference to FIG. 5, the top hard mask layer 105 and the bottom hard mask layer 103 may be removed by, for example, an etching process such as a wet etching process or a dry etching process. In the present embodiment, the top hard mask layer 105 and the bottom hard mask layer 103 may be removed by wet etching process. In some embodiments, the etch rate ratio of the top hard mask layer 105 (or the bottom hard mask layer 103) to the substrate 101 may be between about 100:1 and about 1.05:1, between about 15:1 and about 2:1, or between about 10:1 and about 2:1 during the etching process.

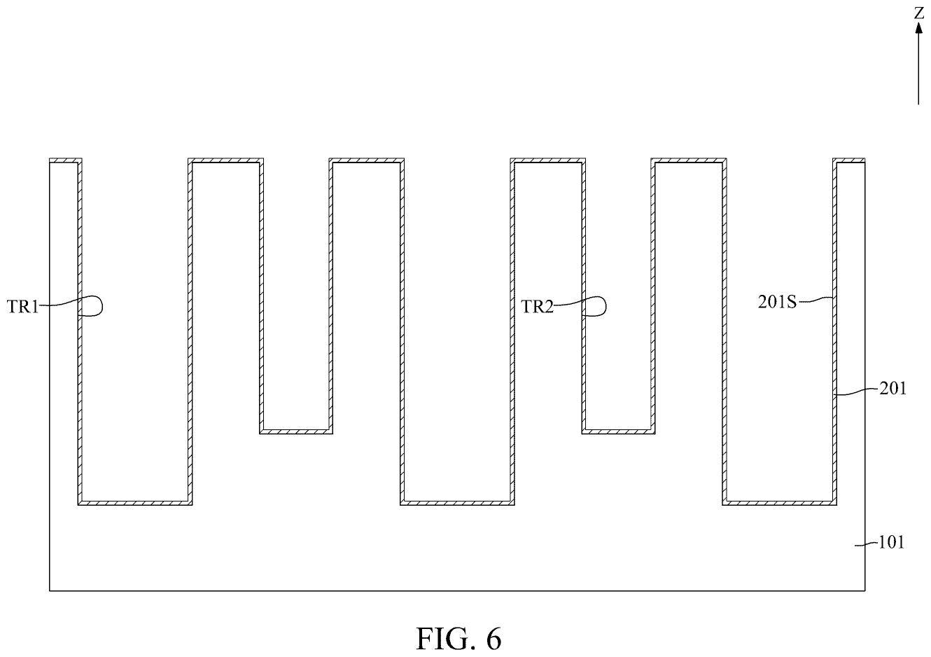

With reference to FIGS. 1 and 6, at step S13, a repair layer 201 may be conformally formed within the plurality of first trenches TR1 and plurality of second trenches TR2.

With reference to FIG. 6, a repairing layer 201 may be conformally formed on the substrate 101, within (or on) the plurality of first trenches TR1, and within (or on) the plurality of second trenches TR2. The part of the repair layer 201 disposed within the first trenches TR1 and the second trench TR2 may include a U-shaped cross-sectional profile. In some embodiments, the sidewall 201S of the repair layer 201 may be substantially vertical.

In some embodiments, the repairing layer 201 may be formed of, for example, silicon. In some embodiments, the repairing layer 201 may be formed by, for example, atomic layer deposition, chemical vapor deposition, or other applicable deposition processes. In some embodiments, the repairing layer 201 may fill seams of the plurality of first trenches TR1 and the plurality of second trenches TR2. In some embodiments, the repairing layer 201 may serve as a buffer or a stress-reducing layer. The repairing layer 201 may be used to mitigate the mechanical stresses caused by the difference in thermal expansion coefficients between the substrate 101 and the insulating material which will be filled in later.

With reference to FIGS. 1, 7, and 8, at step S15, a bottom insulating layer 301 including a lower portion 303 and an upper portion 305 may be conformally formed over the repair layer 201.

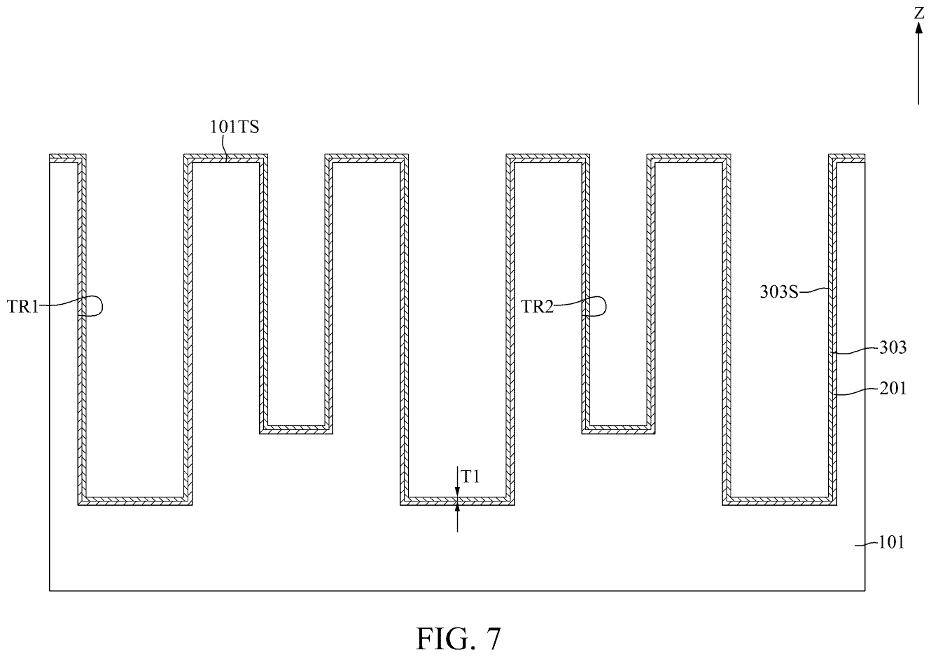

With reference to FIG. 7, the lower portion 303 of the bottom insulating layer 301 may be conformally formed on the repair layer 201. The part of the lower portion 303 disposed within the first trenches TR1 and the second trenches TR2 may include a U-shaped cross-sectional profile. In some embodiments, the sidewall 303S of the lower portion 303 may be substantially vertical. In some embodiments, the thickness T1 of the lower portion 303 of the bottom insulating layer 301 may be about 1 nm.

In some embodiments, the lower portion 303 may be formed of silicon oxide. In some embodiments, the atomic composition of the lower portion 303 may only include silicon and oxygen. In some embodiments, the lower portion 303 may be formed by, for example, a chemical vapor deposition. The precursor for forming the lower portion 303 may only include oxygen gas. The process temperature for forming lower portion 303 of the bottom insulating layer 301 may be lower than 500° C. This low-temperature reaction, combined with a single-gas environment, helps prevent side reactions, in a high temperature environment (e.g., greater than 500° C.), between the substrate 101 and the precursors (e.g., hydrogen gas and/or chlorine), which could otherwise lead to a distorted trench profile and negatively impact the electrical characteristics of the semiconductor device 1.

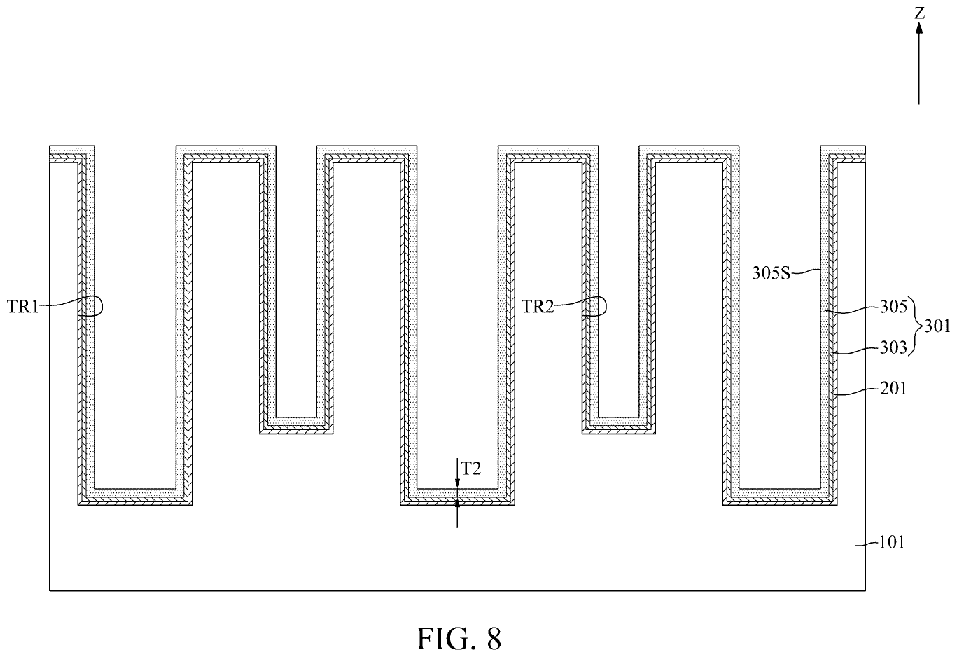

With reference to FIG. 8, the upper portion 305 of the bottom insulating layer 301 may be conformally formed on the lower portion 303 of the bottom insulating layer 301. The part of the upper portion 305 disposed within the first trenches TR1 and the second trenches TR2 may include a U-shaped cross-sectional profile. In some embodiments, the sidewall 305S of the upper portion 305 may be substantially vertical. In some embodiments, the thickness T2 of the upper portion 305 of the bottom insulating layer 301 may be between about 5 nm and about 15 nm.

In some embodiments, the upper portion 305 may be formed of silicon oxide. In some embodiments, the atomic composition of upper portion 305 may only include silicon, oxygen, chlorine, and hydrogen. In some embodiments, the chlorine concentration of the upper portion 305 may be greater than the chlorine concentration of the lower portion 303. In some embodiments, the hydrogen concentration of the upper portion 305 may be greater than the hydrogen concentration of the lower portion 303.

In some embodiments, the upper portion 305 may be formed by, for example, an atomic layer deposition. The precursor for forming the upper portion 305 may include hexachlorodisilane (HCDS), hydrogen gas, and oxygen gas. The process temperature for forming the upper portion 305 of the bottom insulating layer 301 may be greater than or equal to 500° C. Due to the presence of the lower portion 303, the hydrogen gas (and/or out gas such as chlorine) in the precursor used for atomic layer deposition does not react with the substrate 101, ensuring that the profiles of the first trenches TR1 and the second trenches TR2 remain intact.

Detailedly, the precursor for forming the upper portion 305 using atomic layer deposition may include HCDS as the silicon source, oxygen gas as the oxygen source, and hydrogen gas. In some embodiments, Lewis base catalysts like pyridine or trimethylamine may be incorporated to enhance deposition efficiency. The deposition process may involve alternating exposure of the intermediate semiconductor device illustrated in FIG. 7 to precursors, with intermediate purging or pumping to remove residual gases and by-products. The HCDS reacts with hydroxyl groups (—OH) on the substrate surface, forming silicon-chlorine complexes (e.g., —Si₂Cl₄ or —Si₂Cl₅), which are subsequently converted to silicon oxide by reacting with oxygen gas and hydrogen gas. This cycle is repeated to achieve the desired layer thickness (e.g., thickness T2).

In some embodiments, the deposition of the lower portion 303 and the deposition of the upper portion 305 may be performed at the same process chamber which can reduce the manufacture time while ensuring trench profile integrity.

With reference to FIGS. 1, 9, and 10, at step S17, a layer of first insulation material 501 may be conformally formed over the upper portion 305 of the bottom insulating layer 301, and a layer of second insulation layer 503 may be formed over the layer of first insulation material 501 and completely filling the plurality of first trenches TR1 and the plurality of second trenches TR2.

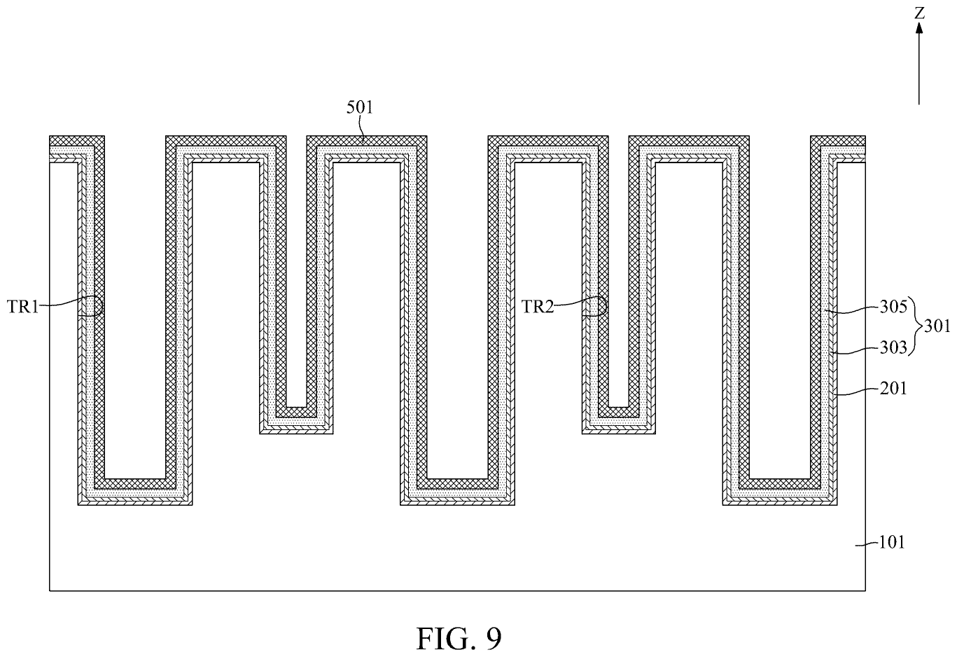

With reference to FIG. 9, the layer of first insulation material 501 may be conformally formed on the layer of bottom insulating layer 301. In some embodiments, the layer of first insulation material 501 may be formed of a material having etching selectivity to the upper portion 305 of the bottom insulating layer 301. In some embodiments, the first insulation material 501 may include silicon nitride or other applicable insulating material. In some embodiments, the layer of first insulation material 501 may be formed of, for example, atomic layer deposition, chemical vapor deposition, or other applicable deposition process.

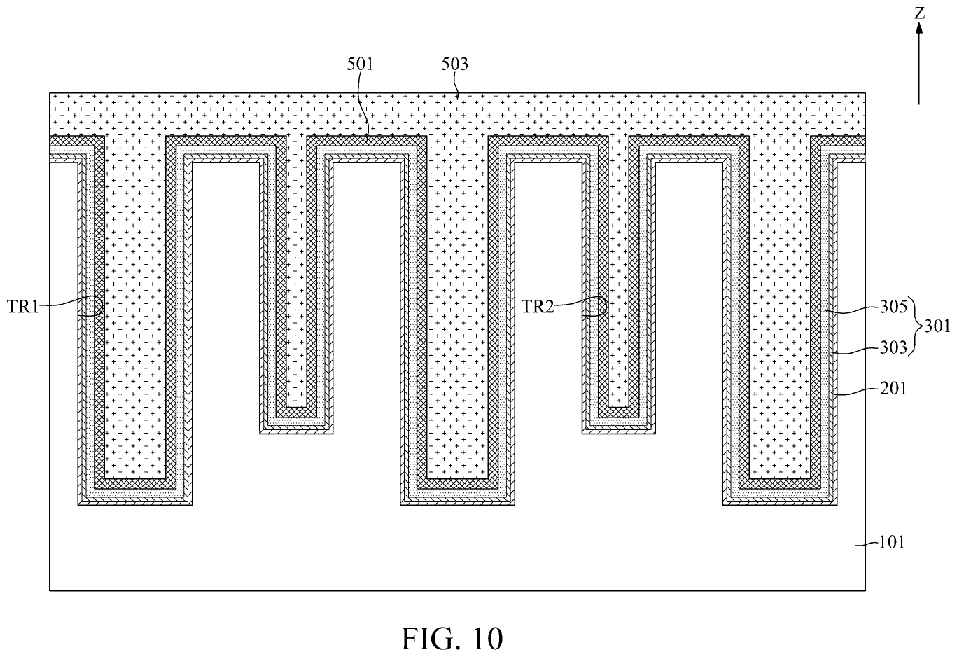

With reference to FIG. 10, the layer of second insulation material 503 may be formed on the layer of first insulation material 501. The layer of second insulation material 503 may completely fill the plurality of first trenches TR1 and the plurality of second trenches TR2. In some embodiments, the second insulation material 503 may include the same material as the bottom insulating layer 301. In some embodiments, the second insulation material 503 may include silicon oxide or other applicable material. In some embodiments, the layer of second insulation material 503 may be formed by, for example, chemical vapor deposition, plasma-enhanced chemical vapor deposition, or other applicable deposition processes.

In some embodiments, a high aspect ratio process may be performed to deposit the layer of second insulation material 503, ensuring complete filling of the trenches TR1, TR2 and covering the layer of first insulation material 501. The high aspect ratio process may involve two stages. During the first stage, a low deposition rate is employed to achieve a more uniform trench filling and reduce the likelihood of void formation. In the second stage, a rapid deposition rate is used to increase overall production efficiency by reducing the deposition time. This high aspect ratio process incorporates both slower and higher deposition rate stages, strategically utilizing the slower deposition rate when it is advantageous for reducing defects and the higher deposition rate for shorter deposition time. Additionally, in some embodiments, the pressure during the high aspect ratio process may range between about 200 Torr and about 760 Torr, while the temperature may be between about 400° C. and about 570° C.

In some embodiments, a two-stage anneal process may be performed after the high aspect ratio process. During the first stage of the two-stage anneal, a lower temperature environment containing one or more oxygen-containing species, such as water, oxygen, nitric oxide, or nitrous oxide, is used. This first stage aims to rearrange and strengthen the silicon oxide network, thereby preventing the formation of voids and the opening of weak seams in the trenches TR1, TR2. Additionally, the lower temperature in the first stage prevents oxygen from reacting with the trench walls and other parts of the substrate 101, which could lead to the formation of undesirable oxide layers.

Subsequently, in the second stage of the two-stage anneal, a higher temperature environment without oxygen is employed. The second stage serves to further rearrange the structure of the second insulation material 503 and drive out moisture, both of which increase the density of the layer of second insulation material 503. The environment during the second stage may be, for example, substantially pure nitrogen, a mixture of nitrogen and noble gases (e.g., helium, neon, argon, or xenon), or a substantially pure noble gas. It may also include reducing gases like hydrogen or ammonia. The second stage facilitates high-temperature densification without causing oxidation of the substrate 101.

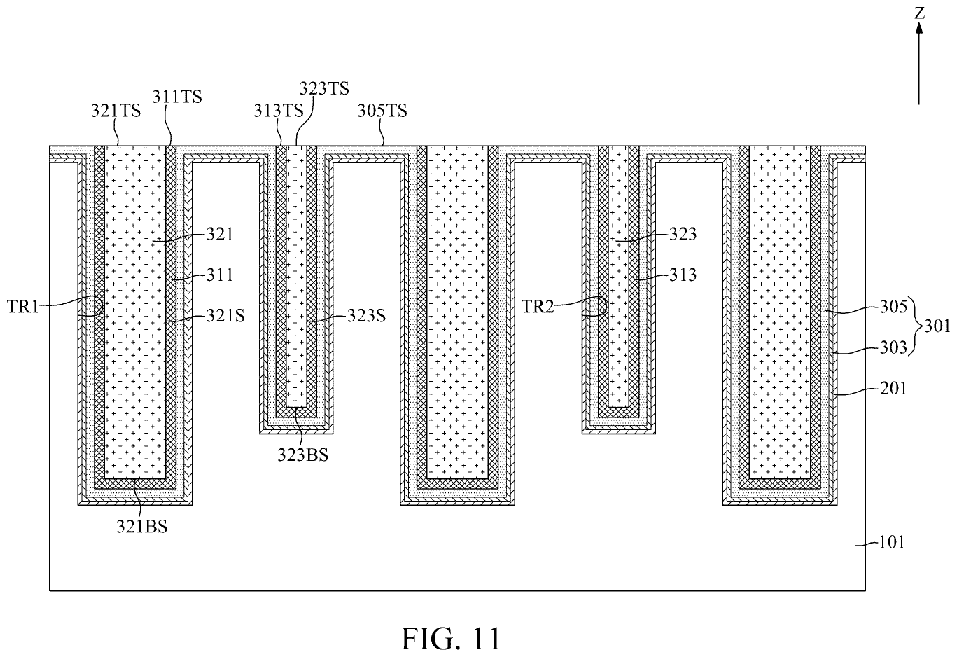

With reference to FIGS. 1 and 11, at step S19, a planarization process may be performed to form a plurality of first top insulating layers 311 and a plurality of first filling layers 321 in the plurality of first trenches TR1 and a plurality of second top insulating layers 313 and the plurality of second filling layers 323 in the plurality of second trenches TR2.

With reference to FIG. 11, the planarization process, such as chemical mechanical polishing, may be performed until the top surface 305TS of the upper portion 305 (i.e., the top surface of the bottom insulating layer 301) is exposed to remove portions of the first insulation material 501 and the second insulation material 503. After the planarization process, the remaining first insulation material 501 may be turned into the plurality of first top insulating layers 311 in the plurality of first trenches TR1 and the plurality of second top insulating layers 313 in the plurality of second trenches TR2, respectively and correspondingly. The remaining second insulation material 503 may be turned into the plurality of first filling layers 321 in the plurality of first trenches TR1 and the plurality of second filling layers 323 in the plurality of second trenches TR2, respectively and correspondingly.

For brevity, clarity, and convenience of description, only one first top insulating layer 311, one second top insulating layer 313, one first filling layer 321, and one second filling layer 323 are described.

The first top insulating layer 311 may include a U-shaped cross-sectional profile. The first top insulating layer 311 may be conformally disposed on the upper portion 305 and within the first trench TR1. The first filling layer 321 may be disposed on the first top insulating layer 311 and within the first trench TR1. Stated differently, the first filling layer 321 may be disposed within the first trench TR1 and the sidewalls 321S and bottom surface 321BS may be surrounded by the first top insulating layer 311.

The second top insulating layer 313 may include a U-shaped cross-sectional profile. The second top insulating layer 313 may be conformally disposed on the upper portion 305 and within the second trench TR2. The second filling layer 323 may be disposed on the second top insulating layer 313 and within the second trench TR2. Stated differently, the second filling layer 323 may be disposed within the second trench TR2 and the sidewalls 323S and bottom surface 323BS may be surrounded by the second top insulating layer 313.

In the current stage, the top surface 321TS of the first filling layer 321, the top surface 311TS of the first top insulating layer 311, the top surface 313TS of the second top insulating layer 313, the top surface 323TS of the second filling layer 323, and the top surface 305TS of the bottom insulating layer 301 may be substantially coplanar.

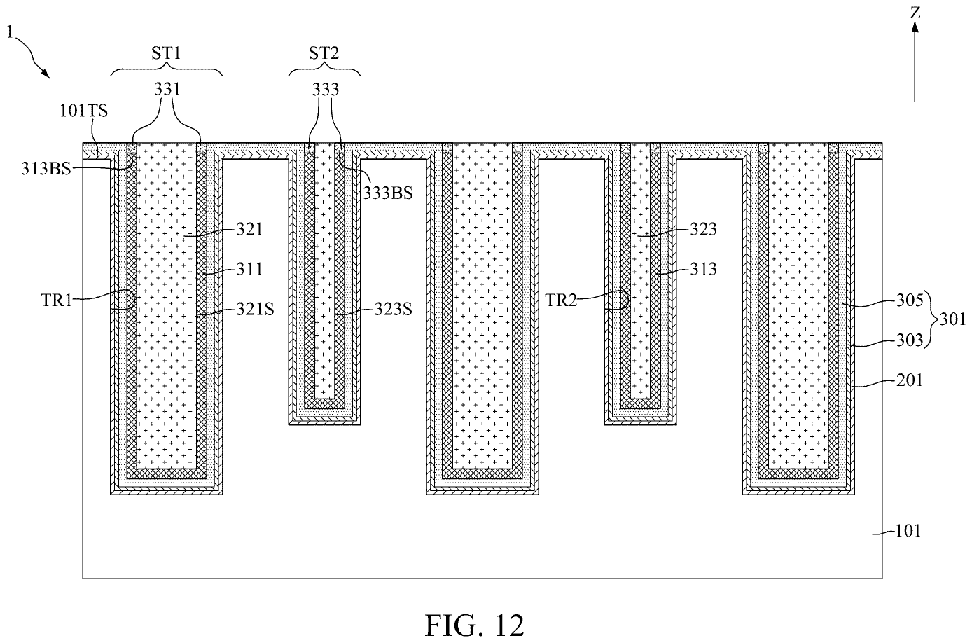

With reference to FIGS. 1 and 12, at step S21, a plurality of first capping layers 331 may be formed on the plurality of first top insulating layers 311 to configure a plurality of first isolation structures ST1, and a plurality of second capping layers 333 may be formed on the plurality of second top insulating layers 313 to configure a plurality of second isolation structures ST2.

With reference to FIG. 12, a surface oxidation process may be performed to oxidize the top ends of the plurality of first top insulating layers 311 and the top ends of the plurality of second top insulating layers 313, which are formed of silicon nitride in the present embodiment. The oxidized ends of the plurality of first top insulating layers 311 and the oxidized end of the plurality of second top insulating layers 313 may be referred to as the plurality of first capping layers 331 and the plurality of second capping layers 333, respectively. The plurality of first capping layers 331 may be disposed on the plurality of first top insulating layers 311, respectively and correspondingly. The plurality of second capping layers 333 may be disposed on the plurality of second top insulating layers 313, respectively and correspondingly. In some embodiments, the bottom surfaces 331BS, 333BS of the first capping layer 331 and the second capping layer 333 may be higher than the top surface 101TS of the substrate 101.

The plurality of first capping layers 331, the plurality of first filling layers 321, the plurality of first top insulating layers 311, the bottom insulating layer 301, the repair layer 201 together configure the plurality of first isolation structures ST1 in the plurality of first trenches TR1. The plurality of second capping layers 333, the plurality of second filling layers 323, the plurality of second top insulating layers 313, the bottom insulating layer 301, the repair layer 201 together configure the plurality of second isolation structures ST2 in the plurality of second trenches TR2.

In some embodiments, the surface oxidation process may be a low-temperature plasma oxidation process. The low-temperature plasma oxidation process for converting silicon nitride into silicon oxide may involve several steps and specific process conditions. First, the intermediate semiconductor device illustrated in FIG. 11 may be loaded into a plasma-enhanced chemical vapor deposition (PECVD) chamber maintained at a low temperature between about 200° C. and about 400° C. Then, a gas mixture of oxygen and an inert gas, such as nitrogen or argon, may be introduced into the chamber with controlled flow rates. The flow rate of oxygen may be set in the range of about 10 standard cubic centimeter per minute (sccm) and about 100 sccm, while the inert gas flow rate can vary from about 50 sccm to about 500 sccm. Radio frequency (RF) power may be applied to generate a low-temperature plasma with a power level of about 50 watts and about 300 watts. The RF power excites the gas mixture, creating reactive species, including oxygen radicals, which play a crucial role in the low-temperature plasma oxidation process.

During the low-temperature plasma oxidation process, the oxygen radicals react with the silicon nitride surface, converting it into silicon oxide without the need for high temperatures. The low-temperature plasma oxidation process is self-limiting, meaning the reaction rate decreases as the silicon nitride layer is converted into silicon oxide. The oxidation time may be carefully controlled to achieve the desired thickness of the silicon oxide layer (i.e., the plurality of first capping layers 331 and the plurality of second capping layers 333), and it typically ranges from a few minutes to tens of minutes, depending on the required film thickness and properties. After the oxidation step, the plasma is deactivated, and a purge gas, usually nitrogen, is introduced into the chamber to remove any residual reactive species and by-products. The plurality of first capping layers 331 and second capping layers 333 may prevent the underlying nitride from being etched during subsequent processes, which could otherwise lead to an uneven surface on the semiconductor device 1 and negatively impact its electrical characteristics.

One aspect of the present disclosure provides a semiconductor device including a substrate; an indentation inwardly positioned in the substrate; a bottom insulating layer including a lower portion conformally positioned along the indentation, and an upper portion conformally positioned on the lower portion and within the indentation; a first top insulating layer conformally positioned on the upper portion and within the indentation; and a first filling layer positioned on and surrounded by the first top insulating layer. A sidewall of the indentation is substantially vertical.

Another aspect of the present disclosure provides a semiconductor device including a substrate; a first filling layer positioned in the substrate; a first top insulating layer including a U-shaped cross-sectional profile, surrounding the first filling layer, and positioned between the substrate and the first filling layer and; a bottom insulating layer including an upper portion including a U-shaped cross-sectional profile, surrounding the first top insulating layer, and positioned between the substrate and the first top insulating layer, and a lower portion including a U-shaped cross-sectional profile, surrounding the upper portion, and positioned between the substrate and the upper portion. A sidewall of the upper portion is substantially vertical.

Another aspect of the present disclosure provides a method for fabricating a semiconductor device including providing a substrate; forming an indentation in the substrate; conformally forming a lower portion within the indentation; and conformally forming an upper portion on the lower portion; conformally forming a first top insulating layer on the lower portion and within the indentation; and forming a first filling layer on the first top insulating layer, completely filling the indentation. The lower portion and the upper portion together configure a bottom insulating layer. A process temperature for forming the lower portion of the bottom insulating layer is less than 500° C., and a process temperature for forming the upper portion of the bottom insulating layer is greater than 500° C.

Due to the design of the semiconductor device of the present disclosure, the lower portion 303 of the bottom insulating layer 301 may be deposited through a low-temperature reaction (e.g., less than 500° C.) in a single-gas environment (oxygen gas only), preventing side reactions between the substrate 101 and precursors (e.g., hydrogen gas and/or chlorine). This helps maintain an intact trench profile and avoids adverse effects on the electrical characteristics of the semiconductor device 1. As a result, the yield and performance of the semiconductor device 1 may be improved.

Although the present disclosure and its advantages have been described in detail, it should be understood that various changes, substitutions and alterations can be made herein without departing from the spirit and scope of the disclosure as defined by the appended claims. For example, many of the processes discussed above can be implemented in different methodologies and replaced by other processes, or a combination thereof.

Moreover, the scope of the present application is not intended to be limited to the particular embodiments of the process, machine, manufacture, composition of matter, means, methods and steps described in the specification. As one of ordinary skill in the art will readily appreciate from the disclosure of the present disclosure, processes, machines, manufacture, compositions of matter, means, methods, or steps, presently existing or later to be developed, that perform substantially the same function or achieve substantially the same result as the corresponding embodiments described herein may be utilized according to the present disclosure. Accordingly, the appended claims are intended to include within their scope such processes, machines, manufacture, compositions of matter, means, methods, and steps.

What is claimed is:

1. A method for fabricating a semiconductor device, comprising:
providing a substrate;
forming an indentation in the substrate;
conformally forming a lower portion within the indentation;
conformally forming an upper portion on the lower portion;
conformally forming a first top insulating layer on the lower portion and within the indentation; and
forming a first filling layer on the first top insulating layer, completely filling the indentation;
wherein the lower portion and the upper portion together configure a bottom insulating layer;
wherein a process temperature for forming the lower portion of the bottom insulating layer is less than 500° C., and a process temperature for forming the upper portion of the bottom insulating layer is greater than 500° C.

2. The method for fabricating the semiconductor device of claim 1, a thickness of the upper portion is between about 5 nm and about 15 nm.

3. The method for fabricating the semiconductor device of claim 1, wherein a thickness of the lower portion is between about 1 nm.

4. The method for fabricating the semiconductor device of claim 1, wherein the lower portion and the upper portion comprise silicon oxide.

5. The method for fabricating the semiconductor device of claim 1, wherein the first top insulating layer comprises silicon nitride.

6. The method for fabricating the semiconductor device of claim 1, wherein the first filling layer comprises silicon oxide.

7. The method for fabricating the semiconductor device of claim 4, wherein an atomic composition of the upper portion comprises silicon, oxygen, chlorine, and hydrogen.

8. The method for fabricating the semiconductor device of claim 4, wherein an atomic composition of the lower portion comprises silicon and oxygen.

9. The method for fabricating the semiconductor device of claim 4, wherein a chlorine concentration of the upper portion is greater than a chlorine concentration of the lower portion.

10. The method for fabricating the semiconductor device of claim 4, wherein a hydrogen concentration of the upper portion is greater than a hydrogen concentration of the lower portion.

11. The method for fabricating the semiconductor device of claim 4, wherein conformally forming the lower portion within the indentation is achieved by chemical vapor deposition with a precursor comprising only oxygen gas.

12. The method for fabricating the semiconductor device of claim 4, wherein conformally forming the upper portion over the lower portion is achieved by atomic layer deposition with a precursor comprising hexachlorodisilane, hydrogen gas, and oxygen gas.

13. The method for fabricating the semiconductor device of claim 1, further comprising forming a repair layer positioned between the lower portion of the bottom insulating layer and the substrate.

14. The method for fabricating the semiconductor device of claim 13, wherein the repair layer comprises silicon.

15. The method for fabricating the semiconductor device of claim 4, wherein conformally forming the lower portion within the indentation and conformally forming the upper portion on the lower portion are achieved in the same process chamber.
